(19) United States
(12) Patent Application Publication
(10) Pub. No.: US 2009/0132186 A1
(43) Pub. Date: May 21, 2009

(54) METHOD AND SYSTEM FOR REPORTING BATTERY STATUS BASED ON CURRENT ESTIMATION

(75) Inventors: Domitille Esnard, Biot (FR); John Walley, Ladera Ranch, CA (US); Sumit Sanyal, Menlo Park, CA (US)

Correspondence Address: FIALA & WEAVER, P.L.L.C.;C/O CPA GLOBAL, P.O. BOX 52050, MINNEAPOLIS, MN, 55402, US

(73) Assignee: Broadcom Corporation, Irvine, CA (US)

(21) Appl. No.: 12/262,527

(22) Filed: Oct. 31, 2008

Related U.S. Application Data
(60) Provisional application No. 60/988,218, filed on Nov. 15, 2007.

(51) Int. Cl. G01R 31/36

(52) U.S. Cl. 702/63

(57) ABSTRACT

A charge stored in a battery is estimated by multiplying estimated charge currents supplied during charge phases and estimated discharge currents discharged during operational modes by the respective amounts of time of charging and discharge. The state of charge of the battery is calculated from the estimated stored charge. Furthermore, parameters of the battery may be measured to be used to adjust the estimated state of charge of the battery. In a first case, the estimated stored charge may be adjusted to a charge value corresponding to the detected completion of a constant current charge phase. In a second case, the estimated stored charge may be adjusted to a charge value corresponding to the detected completion of a constant voltage charge phase. In a third case, the estimated stored charge may be adjusted to a charge value corresponding to a detected predetermined discharge level of the battery.

This application claims the benefit of U.S. Provisional Application No. 60/988,218, filed on Nov. 15, 2007, which is incorporated by reference herein in its entirety.

### BACKGROUND OF THE INVENTION

1. Field of the Invention

The present invention relates to batteries, and in particular, to the tracking of battery stored charge.

2. Background Art

A battery is a device that provides electrical energy used to power an electrical device. A battery typically includes one or more electrochemical cells that store chemical energy, which is converted to electrical energy output by the device to provide power. Batteries are used in a multitude of electrical devices, such as electrical devices that are mobile, are small, and/or are unable to be constantly connected to another power source such as AC (alternating current) power. Batteries may also be used in electrical devices as a backup power source, to provide power when a primary power source is lost.

A rechargeable battery is a type of battery that is becoming increasingly popular. A rechargeable battery can be restored to full charge by the application of electrical energy. Rechargeable batteries based on lithium, such as lithium ion and lithium polymer batteries, are becoming increasingly widespread. A typical charging cycle for a lithium rechargeable battery includes a first charge phase, where a constant current is used to charge the battery (while battery voltage increases), and a second charge phase, where a constant voltage is applied to the battery to finish charging the battery (while the charge current decreases). Typically, the maximum amount of charge that a lithium battery can maintain decreases with age.

Techniques exist for determining an amount of charge stored in batteries (battery “state of charge”). The determined stored charge for a battery can be indicated as a “battery status” for the battery. For example, a battery state of charge may be expressed as a percentage (e.g., “42% remaining capacity”), in terms of an amount of time until battery charge runs out, etc. Conventional techniques for determining the charge stored in a battery for low power devices are inaccurate, and are limited by the power constraints of low power batteries. Furthermore, accurately determining the amount of charge stored in a battery has a high cost in terms of device resources, requiring numerous components and processing resources.

What is desired are ways of determining battery state of charge that are more accurate and less complex than conventional techniques.

### BRIEF SUMMARY OF THE INVENTION

Methods, systems, and apparatuses are described for estimating the state of charge of batteries. A charge stored in a battery may be estimated by multiplying estimated charge currents supplied during charge phases and estimated discharge currents discharged during operational modes by the respective amounts of time of charging and discharging. The state of charge of the battery is calculated from the estimated stored charge.

In one implementation, a method for estimating a state of charge for a rechargeable battery of an electronic device is provided. A first increase in a charge stored in the battery during a first charge phase of the battery in which a substantially constant charge current is received by the battery for a first amount of time is calculated.

A second increase in the charge stored in the battery during a second charge phase of the battery in which a decreasing charge current is received by the battery for a second amount of time is calculated. A reduction of the charge stored in the battery is calculated by multiplying a predetermined discharge current corresponding to an operational mode of the electronic device by an amount of time that the electronic device is in the operational mode. A stored charge in the battery is calculated based on a prior determined stored charge in the battery and at least one of the calculated reduction in the charge, the calculated first increase in the charge, and the calculated second increase in the charge. The state of charge of the battery is calculated based on the calculated stored charge.

In another implementation, a battery manager is provided. The battery manager includes a first charge phase charge calculator, a second charge phase charge calculator, a third charge phase charge calculator, a summer, and a state of charge calculator. The first charge phase charge calculator is configured to calculate a first increase in a charge stored in the battery during a first charge phase of the battery in which a substantially constant charge current is received by the battery for a first amount of time. The second charge phase charge calculator is configured to calculate a second increase in the charge stored in the battery during a second charge phase of the battery in which a decreasing charge current is received by the battery for a second amount of time. The third charge phase charge calculator is configured to calculate a reduction of the charge stored in the battery by multiplying a predetermined discharge current corresponding to an operational mode of the electronic device by an amount of time that the electronic device is in the operational mode. The summer is configured to calculate a stored charge in the battery based on a prior determined stored charge in the battery and at least one of the calculated reduction in the charge, the calculated first increase in the charge and the calculated second increase in the charge. The state of charge calculator is configured to calculate the state of charge of the battery based on the calculated stored charge.

Furthermore, methods, systems, and apparatuses are described for adjusting the estimated state of charge based on measured parameters of the battery. In a first case, the estimated stored charge may be adjusted to a charge value corresponding to the detected completion of a constant current charge phase. In a second case, the estimated stored charge may be adjusted to a charge value corresponding to the detected completion of a constant voltage charge phase. In a third case, the estimated stored charge may be adjusted to a charge value corresponding to a detected predetermined discharge level of the battery.

In one implementation, a method for adjusting the estimated state of charge is provided. A voltage and/or current of the battery is/are measured to determine a completion of a first charge phase. The calculated stored charge is adjusted to a charge value corresponding to the completion of the first charge phase. The state of charge of the battery is calculated based on the adjusted stored charge.

In another implementation, a current of the battery is measured to determine a completion of a second charge phase. The calculated stored charge is adjusted to a charge value corresponding to the completion of the second charge phase. The state of charge of the battery is calculated based on the adjusted stored charge.

In another implementation, a voltage of the battery is measured to determine whether the battery is discharged to a predetermined amount of stored charge. The calculated stored charge is adjusted to the predetermined amount of stored charge. The state of charge of the battery is calculated based on the adjusted stored charge.

In still another implementation, the battery manager includes a stored charge adjuster configured to measure a parameter of the battery, and to calculate an adjusted stored charge for the battery according to the measured parameter.

For instance, the stored charge adjuster may include a first beacon point detector configured to measure a voltage and/or current of the battery to determine a completion of the first charge phase, and to adjust the calculated stored charge to a charge value corresponding to the completion of the first charge phase.

The stored charge adjuster may include a second beacon point detector configured to measure a current of the battery to determine a completion of the second charge phase, and to adjust the calculated stored charge to a charge value corresponding to the completion of the second charge phase.

Still further, the stored charge adjuster may include a third beacon point detector configured to measure a voltage of the battery to determine whether the battery is discharged to a predetermined amount of stored charge, and to adjust the calculated stored charge to the predetermined amount of stored charge.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a graphical representation of example charge characteristics of a battery.

FIG. 2 shows a graph illustrating a typical charging cycle for a rechargeable battery.

FIG. 3 shows the battery of FIG. 1 during a discharge period.

FIG. 4 shows a block diagram of a battery management system, according to an example embodiment of the present invention.

FIG. 5 shows a flowchart providing example steps for determining battery state of charge, according to an example embodiment of the present invention.

FIG. 6 shows a block diagram of a battery manager, according to an example embodiment of the present invention.

FIG. 7 shows a block diagram of an example of the battery management system of FIG. 4, according to an embodiment of the present invention.

FIG. 8 shows graphs of battery current, capacity, and voltage during charge and discharge phases of a battery, according to an example embodiment of the present invention.

FIG. 9 shows a graph of various charge waveforms according to which a battery may be charged during a constant voltage charge phase, according to example embodiments of the present invention.

FIG. 10 shows a table that lists example operational mode currents, according to an embodiment of the present invention.

FIG. 11 shows a flowchart providing example steps for adjusting an estimated battery state of charge, according to an example embodiment of the present invention.

FIGS. 12-14 each show a respective flowchart that is an example embodiment of the flowchart of FIG. 1.

FIG. 15 shows a block diagram of an example of the battery management system of FIG. 4, according to an embodiment of the present invention.

FIG. 16 shows a graph of the state of charge for a battery during an example discharge and charge cycle, according to an embodiment of the present invention.

FIG. 17 shows a block diagram of an electrical device that incorporates a battery manager, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

### Example Battery Characteristics

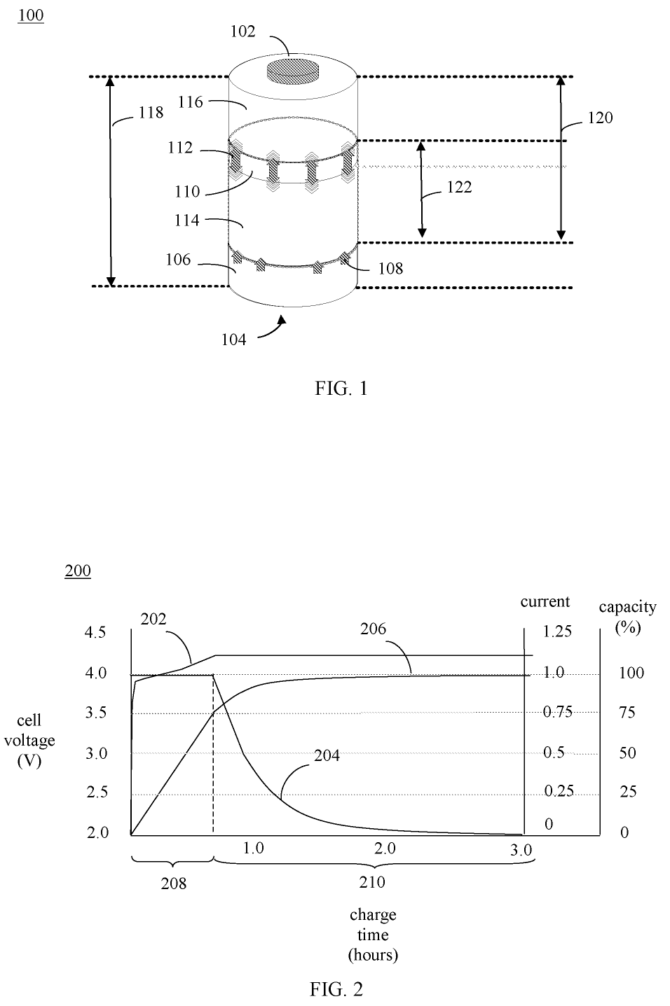

Embodiments of the present invention relate to batteries. A battery is a device that provides electrical energy used to power an electrical device. A battery typically includes one or more electrochemical cells that store chemical energy, which is converted to electrical energy that is output by the device to provide power. FIG. 1 shows a view representing charge characteristics of a battery 100, which are described in detail below. Battery 100 has a first terminal 102 (e.g., negative or positive polarity) and a second terminal 104 (with polarity opposite that of first terminal 102). Battery 100 is a rechargeable battery formed of a material that enables recharging. For example, battery 100 may be a lithium-based rechargeable battery, such as a lithium ion (Li-ion) or lithium ion polymer (Li-ion polymer) battery. Rechargeable batteries can be restored to full charge by the application of electrical energy.

FIG. 2 shows a graph 200 illustrating waveforms that represent a typical charging cycle for a rechargeable lithium-based (e.g., lithium ion or lithium polymer) battery. Graph 200 has a horizontal axis that indicates units of charge time (hours). Graph 200 has a first vertical axis indicating cell voltage (Volts) with regard to a voltage waveform 202, a second vertical axis indicating current with regard to a current waveform 204, and a third vertical axis indicating charge capacity percentage (%) with regard to a charge waveform 206. As shown in FIG. 2, current waveform 204 includes a first charge phase 208 and a second charge phase 210. During first charge phase 208, a substantially constant current is used to charge the battery (while battery voltage increases as indicated by voltage waveform 202). First charge phase 208 typically is complete when battery 100 reaches its maximum typical voltage. During second charge phase 210, a substantially constant voltage is applied to the battery to finish charging the battery (while the charge current decreases as indicated by current waveform 204). After second charge phase 210, battery 100 is charged to its maximum charge capacity (100%), as indicated by charge waveform 206. Typically, the maximum amount of charge that a rechargeable battery can maintain decreases with age.

The behavior of a lithium battery is complex, involving chemical reactions, reaction kinetics, and diffusion processes. Thus, a circuit equivalent model of a lithium battery is complex, as it typically includes non-linear components. In FIG. 1, the illustrated total volume of battery 100 represents the initial (e.g., when the battery is manufactured) total charge capacity of battery 100 (also indicated by initial total charge 118 in FIG. 1). A charged portion 114 of battery 100 is shown in FIG. 1 that contains available charge. An uncharged portion 116 of battery 100 is shown in FIG. 1. Uncharged portion 116 is a charge-free or uncharged portion of battery 100, which may be uncharged because battery 100 was not fully charged on a previous charge cycle, because charge has recently been supplied by battery 100, and/or for other reason. As battery 100 ages, cell(s) of battery 100 will oxidize. An oxidized portion 106 shown at the bottom of battery 100 in FIG. 1 represents a portion of the total charge volume of battery 100 that is lost due to aging related oxidation. As indicated by arrows 108, a size of oxidized portion 106 increases during the life of battery 100. Thus, oxidized portion 106 represents a decrease over time in the amount of charge that battery 100 may store due to aging-related oxidation.

A charge process equilibrium portion 110 of battery 100 is also shown in FIG. 1. Charge process equilibrium portion 110 represents an unknown state of battery 100 due mainly to the discharge rate of battery 100. As indicated by arrows 112 in FIG. 1, the charge volume of portion 110 may fluctuate. The charge volume of portion 110 depends on various parameters, such as the aging of battery 100, a state of charge of battery 100, a history of battery 100, a temperature of battery 100, etc. In portion 110, electrons are in transition after a charging or discharging event, but typically come to equilibrium after time (e.g., after 1 hour).

A state of health (SOH) 120 of battery 100 is indicated in FIG. 1. SOH 120 represents a total charge capacity of battery 100—an amount of charge that may actually be available in battery 100, taking into account aging of battery 100. SOH 120 of battery 100 may be calculated according to

SOH=ICC×(100%−DCCP) Equation 1

where
ICC=initial charge capacity of battery 100, and
DCCP=decreased charge capacity of battery 100.
   The decreased charge capacity of battery 100 may be due to oxidized portion 106. For instance, if battery 100 has an initial charge capacity of 130 mAH (milli-Ampere-hour) (initial total charge 118) that has decreased by 20%, SOH 120 of battery 100 may be calculated as

SOH=130 mAH(100%−20%)=104 mAH.

In this example, when fully charged, battery 100 is able to provide 104 mAH of charge, which is a reduction from the initial charge capacity of battery 100 of 130 mAH.

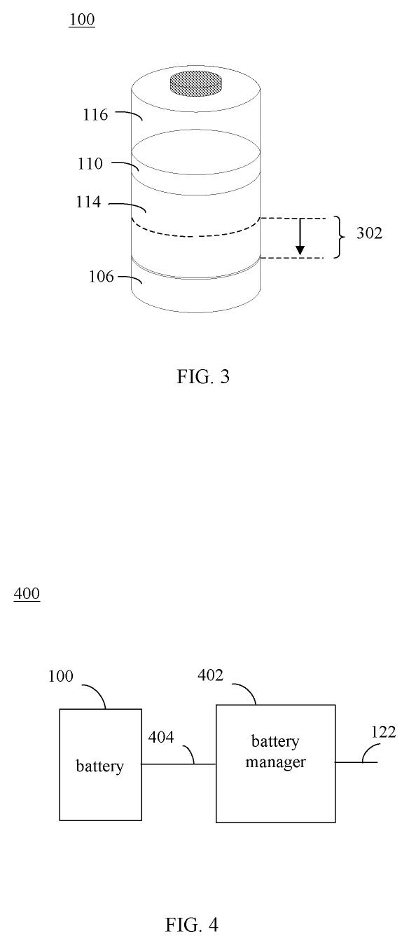

A state of charge (SOC) 122 of battery 100 represents an amount of charge currently in battery 100 that can be used. SOC 122 is typically defined as a percentage. SOC 122 of battery 100 is conventionally determined according to a coulomb counting approach. According to the coulomb counting approach, charging and/or discharging of battery 100 is monitored to determine the amount of charge entering or leaving battery 100. For example, FIG. 3 shows battery 100 during a discharge period. In FIG. 3, an amount of charge represented by discharge portion 302 leaves battery 100, decreasing the amount of charged portion 114 of battery 100. This amount of discharge may be estimated. During a time duration T, an amount of charge Q entering or leaving battery 100 may be estimated according to

Q=I×T Equation 2

where
I=a current flowing into or out of battery 100 during time duration T.
   SOC 122 may be calculated based on SOH 120, according to

SOC (%)=RC/SOH Equation 3

where
RC=remaining charge stored in battery 100.
   RC may be calculated in various ways, including according to

RC=SOH−Q Equation 4

where Q is determined according to Equation 2 above, such that T is the time duration measured from last time when battery 100 was fully charged.

An electrical device that uses battery 100 for power may use the coulomb counting approach to perform its battery fuel gauging. For instance, the device may use the coulomb counting approach to determine SOC 122, determining that battery 100 is “42% full,” for example. To make this determination using the coulomb counting approach, the electrical device tracks SOH 120 for battery 100 (i.e., determining the capacity of battery 100, which may change over the time due to aging, bad usage of battery 100, and/or other factors). It is difficult to accurately measure the charge stored in a battery by measuring the current flowing into and out of the battery. In particular, towards the end of the constant voltage charging phase (second charge phase 210), the level of current entering battery 100 is very small. For example, the amount of current may be less than 5 mA for a 100 mAH battery. Any inaccuracy in the current measuring components of the electrical device will cause the current measurement to be incorrect. The electrical device typically will have a fuel gauging resistor and an analog to digital converter (ADC) that track the charge current during the whole charging cycle. Such components must be relatively precise to provide accurate results, and undesirably add to the cost of the electrical device.

Embodiments of the present invention enable the determination of battery state of charge in a less complex and less expensive manner than conventional techniques. Example embodiments of the present invention are described in detail in the following section.

### Example Embodiments

The example embodiments described herein are provided for illustrative purposes, and are not limiting. The examples described herein may be adapted to any type of electrical device. Furthermore, additional structural and operational embodiments, including modifications/alterations, will become apparent to persons skilled in the relevant art(s) from the teachings herein.

In embodiments of the present invention, battery state of charge may be determined in a manner that does not require precision measuring components. For example, the fuel gauging resistor that is present in conventional devices for Coulomb counting current measuring is not required in embodiments, and thus a bill of materials related to battery management may be reduced, as well as no longer needing two pins typically associated with the fuel gauging resistor. The accuracy of the remaining components used for determining battery state of health may be reduced, in embodiments. Furthermore, power consumption is reduced. The extra power consumption associated with a fuel gauging resistor is not required. An accuracy in determining battery state of charge may be improved, in embodiments.

Embodiments have advantages as compared to voltage measuring techniques for determining battery state of charge. Battery impedance variations due to temperature, frequency, history, state of charge, discharge rate, and battery aging have little to no adverse impact in embodiments. In contrast, variations in battery impedance cause voltage measuring techniques for determining battery state of charge to be inaccurate.

In an embodiment, a state of charge of a battery, such as battery 100, is determined by estimating an amount of charge being stored in the battery during charging phases for the battery and estimating an amount of charge flowing out of the battery during operational phases for the battery. The state of charge determined by estimation in this manner may be adjusted according to battery parameters (e.g., current and/or voltages) that are measured. For example, at particular points in the charging phases and/or operational phases for the battery, actual currents and/or voltages associated with the battery may be measured. The measured actual currents and/or voltages may be used to adjust/correct the estimated state of charge, as desired.

The following subsection describes example embodiments for estimating the state of charge of a battery, followed by a subsection describing example embodiments for adjusting the estimated state of charge.

### Example Embodiments for Estimating State of Charge

FIG. 4 shows a battery management system 400, according to an example embodiment of the present invention. Battery management system 400 includes battery 100 and a battery manager 402. Battery manager 402 is coupled to battery 100 by an electrical connection 404. Electrical connection 404 may include a first electrical connection to a positive terminal (e.g., terminal 102 or terminal 104) of battery 100, and a second electrical connection to a negative terminal of battery 100.

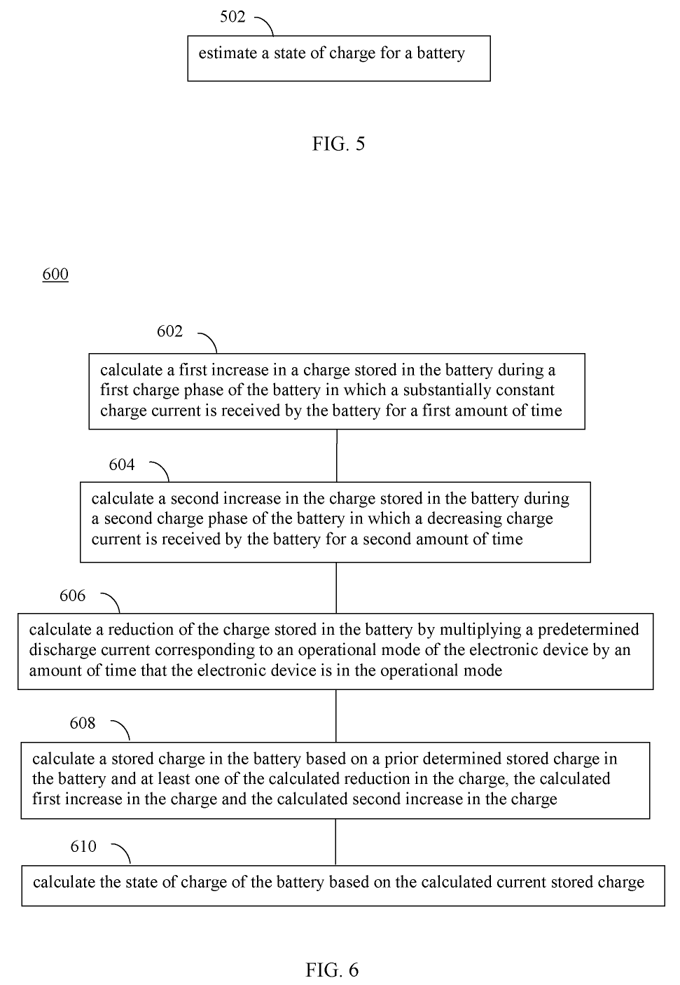

As shown in FIG. 4, battery manager 402 may be configured to estimate SOC 122 for battery 100, and may further be configured to adjust an estimated SOC 122 (as described in the next section). For example, FIG. 5 shows a process 502 that may be performed by battery manager 402. As shown in FIG. 5, in process 502, a state of charge for a battery is estimated. Process 502 may be performed by battery manager 402 in various ways, in embodiments.

For instance, FIG. 6 shows a flowchart 600 providing example steps for estimating battery state of charge, according to an example embodiment of the present invention. Flowchart 600 illustrates an example way of performing process 502. Battery management system 400 may perform flowchart 600, in an embodiment. Other structural and operational embodiments will be apparent to persons skilled in the relevant art(s) based on the discussion regarding flowchart 600.

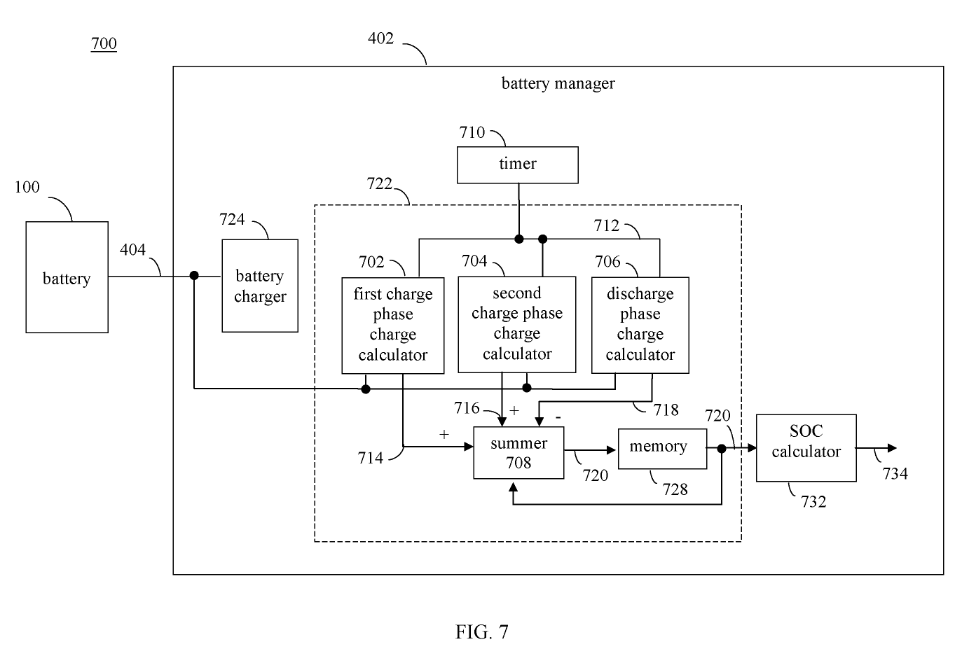

For instance, FIG. 7 shows a block diagram of a battery management system 700, which is an example of battery management system 400 shown in FIG. 4, according to an embodiment of the present invention. As shown in FIG. 7, system 700 includes battery 100 and battery manager 402. Battery manager 402 includes a timer 710, a stored charge estimator 722, a battery charger 724, and a state of charge (SOC) calculator 732. Stored charge estimator 722 includes a first charge phase charge calculator 702, a second charge phase charge calculator 704, a discharge phase charge calculator 706, a summer 708, and a memory 728. Timer 710 is configured to generate a clock signal 712 that indicates a current time.

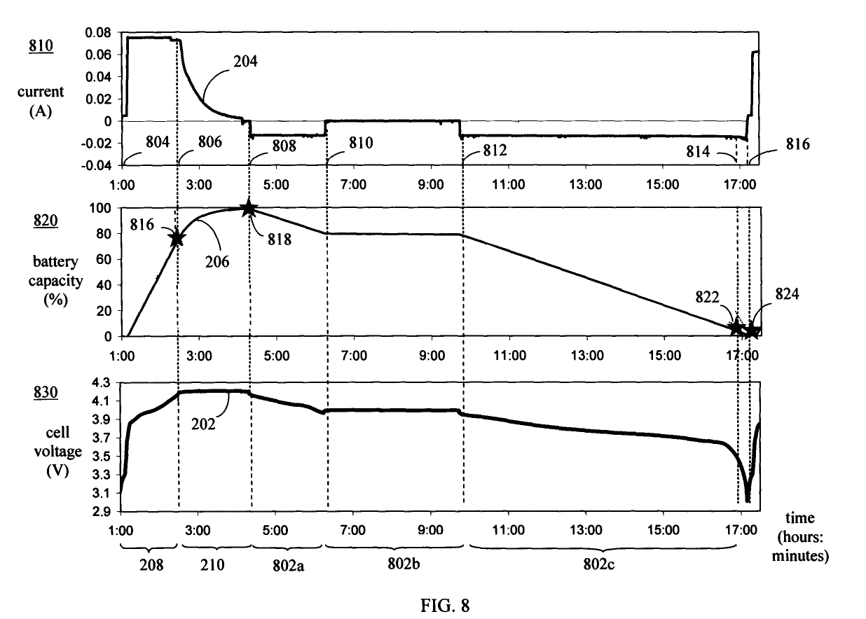

Flowchart 600 of FIG. 6 is described as follows with regard to battery manager 402 shown in FIG. 7, and with regard to graphs shown in FIG. 8, for purposes of illustration. FIG. 8 shows graphs of current, charge capacity, and voltage during charge and discharge phases of battery 100, according to an example embodiment. A first graph 810 shown in FIG. 8 indicates an example current waveform for charging and discharging battery 100 (shows current versus time). A second graph 820 shown in FIG. 8 indicates a charge waveform that illustrates an example battery capacity (in terms of storage percentage) associated with the charging and discharging of battery 100 (shows battery capacity percentage versus time). A third graph 830 shown in FIG. 8 indicates an example voltage waveform associated with the charging and discharging of battery 100 (shows voltage versus time). First, second, and third graphs 810, 820, and 830 respectively show current waveform 204, charge waveform 206, and voltage waveform 202 during first and second charge phases 208 and 210, and show example further portions of current waveform 204, charge waveform 206, and voltage waveform 202 not shown in FIG. 2 during an example discharge phase for battery 100. Graphs 810, 820, and 830 are shown on a common timeline in FIG. 8.

Flowchart 600 is described as follows. Note that any number of steps 602, 604, and 606 of flowchart 600 may be performed prior to performing steps 608 and 610 of flowchart 600, in embodiments. Flowchart 600 begins with step 602. In step 602, a first increase in a charge stored in the battery during a first charge phase of the battery in which a substantially constant charge current is received by the battery for a first amount of time is calculated. For instance, in an embodiment, first charge phase charge calculator 702 may be configured to perform step 602. As shown in graph 810 of FIG. 8 (and as described above with respect to FIG. 2), during first charge phase 208, a substantially constant current is used to charge the battery (while battery voltage increases as indicated by voltage waveform 202). In FIG. 7, battery charger 724 supplies a substantially constant charge current to battery 100 over electrical connection 404 during first charge phase 208.

First charge phase charge calculator 702 may be configured to determine the length of time (as indicated by monitoring clock signal 712) that the constant charge current is provided by battery charger 724 to battery 100. As shown in FIG. 8, the constant charge current is provided during first charge phase 208, which has a length of time from a first time 804 to a second time 806. First charge phase charge calculator 702 may be configured to multiply the constant charge current provided by battery charger 724 to battery 100 by the determined length of time to estimate an increase in the charge stored in battery 100 during first charge phase 208. As shown in FIG. 7, first charge phase charge calculator 702 generates a first charge increase 714, which includes the determined estimate of the increase in charge stored in battery 100 provided by the constant charge current.

In step 604, a second increase in the charge stored in the battery during a second charge phase of the battery in which a decreasing charge current is received by the battery for a second amount of time is calculated. For instance, in an embodiment, second charge phase charge calculator 704 may be configured to perform step 604. As shown in third graph 830 of FIG. 8 (and described above with respect to FIG. 2), during second charge phase 210, a substantially constant voltage is applied to battery 100 to finish charging battery 100 (while the charge current decreases as indicated by current waveform 204).

After second charge phase 210, battery 100 is charged to its maximum charge capacity (100%), as indicated by charge waveform 206. In FIG. 7, battery charger 724 supplies an exponentially decreasing charge current to battery 100 over electrical connection 404 during second charge phase 210.

Second charge phase charge calculator 704 may be configured to determine the length of time (as indicated by clock signal 712) that the decreasing charge current is provided by battery charger 724 to battery 100. As shown in FIG. 8, the decreasing charge current is provided during second charge phase 210, which has a length of time from second time 806 to a third time 808. Second charge phase charge calculator 704 may be configured to integrate current waveform 204 over the determined length of time to estimate an increase in the charge stored in battery 100 during second charge phase 210. As shown in FIG. 7, second charge phase charge calculator 704 generates a second charge increase 716, which includes the determined estimate of the increase in charge stored in battery 100 provided by the decreasing charge current.

Second charge phase charge calculator 704 may be configured to calculate second charge increase 716 in various ways. For example, in an embodiment, an equation may be configured that approximates current waveform 204 during second charge phase 210 shown in FIG. 8. Second charge phase charge calculator 708 may be configured to integrate the current waveform equation over the determined length of time calculate second charge increase 716. In another embodiment, an equation may be configured that approximates charge waveform 206 directly (e.g., includes an exponentially decreasing function term). In another embodiment, second charge phase charge calculator 704 may store or access a lookup table that may store current values that approximate current waveform 204 (that may be multiplied by time values to generate charge values) or charge values that approximate charge waveform 206 during second charge phase 210. The charge values may be summed over the determined length of time to estimate the increase in the charge stored in battery 100 during second charge phase 210.

An example function for estimating the charge stored (StoCh) in battery 100 shown below as Equation 5:

$$StoCh = \frac{1}{{( B \times T + 1 )}^{2}} \qquad Equation 5$$

where:

T=an amount of time (milliseconds), beginning when the constant charge voltage is applied to battery 100, and

B=a charge factor.

B may be selected in a manner to configure Equation 5 to track an actual charge waveform for battery 100 as closely as desired.

For instance, Equation 6 shown below is an example of Equation 5, and may be used to estimate the charge stored in battery 100 during and/or immediately after second charge phase 210:

$$StoCh = {SoH}_{avg} - ( {SoH}_{avg} - {StoCh}_{CC} ) \times \frac{1}{{( \begin{matrix}\frac{{StoCh}_{CC}}{{( {StoCh}_{CCth} )}^{2}} \times \\ Kcv \times T + 1\end{matrix} )}^{2}} \qquad Equation 6$$

where:

StoCh_{CC}=an amount of charge stored in battery 100 during the prior constant current charge phase (μC),

StoCh_{CCth}=a theoretical amount of charge stored in battery 100 during a constant current charge phase (μC),

SoH_{avg}=an average of prior determined State-of-Health (μC) values for battery 100, and

Kcv=a quality charge factor (milliamperes).

StoCh_{CCth} may be determined in various ways, including by referencing a datasheet for battery 100. The datasheet may indicate that for a given constant charge current (during first charge phase 208), battery 100 will be a particular percentage full of charge at the transition from first charge phase 208 to second charge phase 210. For example, a datasheet may indicate that if a constant charge current of 100 milliamps is applied to battery 100 for the length of first charge phase 208, battery 100 will be 70% full at the transition from first charge phase 208 to second charge phase 210. If battery 100 is a 100 mAH battery, and thus may contain a maximum of 360 Coulombs (C) of charge, battery 100 will contain 252 C (360 C×70%=252 C) of charge at the transition.

In this example, StoCh_{CCth} is equal to 252 C.

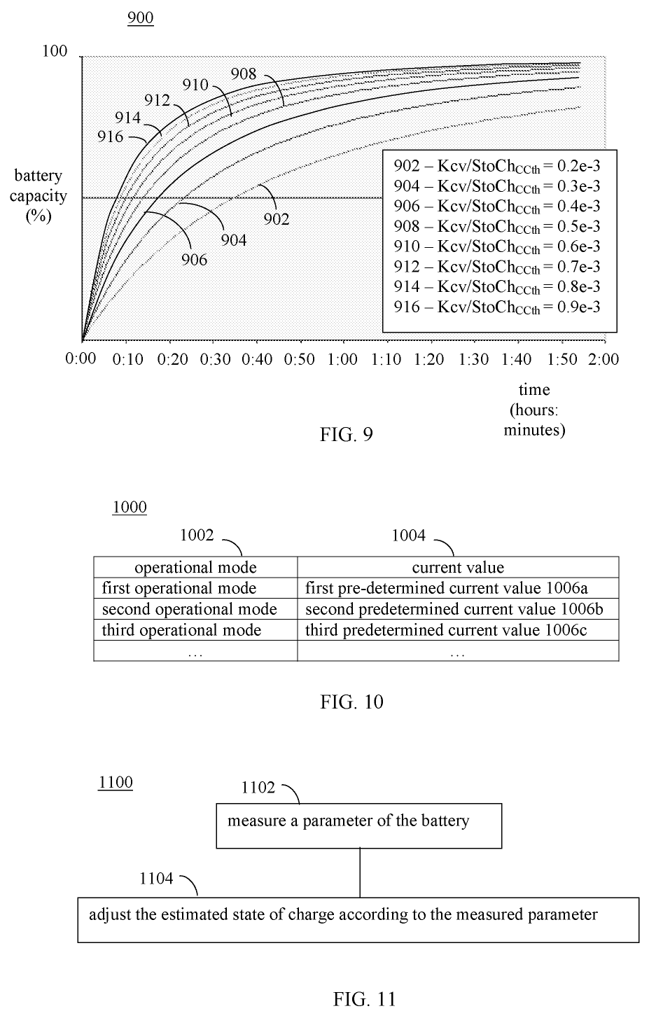

Kcv is a quality of charge factor during second charge phase 210. Kcv is dependent on a battery type for battery 100, and is inversely related to the value of the constant charge current used to charge battery 100 during the first charge phase 208 (e.g., if the constant charge current supplied during first charge phase 208 was relatively high, Kcv may be selected to reduce the charge current supplied during second charge phase 210). Kcv may be determined in various ways. For example, Kcv may be selected from a table or graph, such as a graph 900 shown in FIG. 9. Graph 900 shows a plot of various charge waveforms that may be selected to charge battery 100 during second charge phase 210 for various values of Kcv/StoCh_{CCth} (having units of sec⁻¹). First-eighth charge waveforms 902-916 are shown in FIG. 9 for illustrative purposes. In embodiments, any number of charge waveforms corresponding to any number of values of Kcv may be present. A value for Kcv/StoCh_{CCth} is shown in FIG. 9 corresponding to each of first-eighth charge waveforms 902-916.

For example, a datasheet may indicate that battery 100 is a 135 mAH battery, and that battery 100 will be 70% full at the transition from first charge phase 208 to second charge phase 210. In such case, battery 100 may contain a maximum of 486 C of charge, and may contain 340 C (486 C×70%=340 C) of charge at the transition, and thus StoCh_{CCth} is equal to 340 C (340,000 mC). If charge waveform 906 in graph 900 is selected as best fitting a charge profile for battery 100 during second charge phase 210, Kcv may be determined to be 136 milliamps (0.0004 sec¹×340,000 mC).

Note that Equations 5 and 6 are example formulas that may be used to estimate the amount of charge stored in battery 100 during a portion or the entirety of second charge phase 210. Equations 5 and 6 are provided for purposes of illustration, and are not intended to be limiting. Any number of formulas that approximate charge waveform 206 during second charge phase 210 within a desired degree of accuracy may be determined and may be used by second charge phase charge calculator 704 to generate second charge increase 716.

Referring to FIG. 6, in step 606, a reduction of the charge stored in the battery is calculated by multiplying a predetermined discharge current corresponding to an operational mode of the electronic device by an amount of time that the electronic device is in the operational mode. For instance, in an embodiment, discharge phase charge calculator 706 may be configured to perform step 606. Discharge phase charge calculator 706 may store or access a plurality of predetermined discharge current values that correspond to a plurality of operational modes of an electronic device powered by battery 100. When the electronic device enters one of the operational modes, discharge phase charge calculator 706 may select the predetermined discharge current value corresponding to the operational mode, and may use the selected pre-determined discharge current value to determine an amount of a reduction in charge stored in battery 100 while the electronic device operates in the operational mode. An electronic device that is powered by battery 100 may have any number different types of operational modes, including a sleep mode, a low power mode (e.g., a Bluetooth® sniff mode), a hold mode, a park mode, and off mode, a connected mode, etc. Each operational mode may have a corresponding expected discharge current value that may be used to determine an amount of reduction in charge while battery 100 operates in that mode.

As shown in FIG. 8, graphs 810, 820, and 830 each include a first operational time period 802a corresponding to a first operational mode, a second operational time period 802b corresponding to a second operational mode, and a third operational time period 802c corresponding to a third operational mode are indicated. First operational time period 802a has a length of time from third time 808 to a fourth time 810. Second operational time period 802b has a length of time from fourth time 810 to a fifth time 812. Third operational time period 802c has a length of time from fifth time 812 to a seventh time 816. Three time periods 802 are shown in FIG. 8 for illustrative purposes. In embodiments, any number of time periods 802 corresponding to operational modes of battery 100 may be present between charging events for battery 100.

As shown in FIG. 8, battery 100 may enter the first operational mode at third time 808. As shown in graph 810, battery 100 provides a substantially constant current during first operational time period 802a while in the first operational mode. As shown in graph 820, battery 100 discharges at a substantially constant rate during first operational time period 802a. For instance, the first operational mode may be a connected mode. Discharge phase charge calculator 706 may be configured to determine the length of time (by monitoring clock signal 712) of first operational time period 802a. Furthermore, discharge phase charge calculator 706 may receive a predetermined discharge current value estimated to be provided by battery 100 while the electronic device operates in the first operational mode. Discharge phase charge calculator 706 may be configured to multiply the received predetermined discharge current value by the determined length of time to estimate a reduction in the charge stored in battery 100 during operational time period 802a. As shown in FIG. 7, discharge charge phase charge calculator 706 generates a charge reduction 718, which includes the determined estimate of the reduction in charge stored in battery 100 during operational time period 802a.

In a similar manner, battery 100 may enter a second operational mode at fourth time 810. As shown in graph 810, battery 100 provides a substantially constant current during second operational time period 802b while in the second operational mode (which is a near zero current level). As shown in graph 820, battery 100 discharges at a very low-to-negligible rate during second operational time period 802b while in the second operational mode. For instance, the second operational mode may be a sleep mode.

Discharge phase charge calculator 706 may be configured to determine the length of time (by monitoring clock signal 712) of second operational time period 802b. Discharge phase charge calculator 706 may receive a predetermined discharge current value estimated to be provided by battery 100 while the electronic device operates in the second operational mode. Discharge phase charge calculator 706 may be configured to multiply the received predetermined discharge current value by the determined length of time of time period 802b to estimate a reduction in the charge stored in battery 100 during operational time period 802b. As described above, discharge charge phase charge calculator 706 may generate charge reduction 718 to include the determined estimate of the reduction in charge stored in battery 100 during operational time period 802b.

Furthermore, battery 100 may begin enter the third operational mode at fifth time 812 for the length of time period 802c. In a similar manner as described above, discharge phase charge calculator 706 may be configured to determine charge reduction 718 for the third operational mode over time period 802c by multiplying the predetermined discharge current value for the third operational mode by the length of time of time period 802c.

Discharge phase charge calculator 706 may be configured to determine charge reduction 718 for any number of different operational modes over any number of corresponding time periods, depending on the operational usage of battery 100. Calculated charge reductions for any number of operational time periods 802 may be included in charge reduction 718.

Discharge phase charge calculator 706 may receive predetermined discharge current values corresponding to various operational modes from storage. For instance, FIG. 10 shows an example operational mode current table 1000, according to an embodiment of the present invention. As shown in FIG. 10, table 1000 includes an operational mode column 1002 and a current value column 1004. Operational mode column 1002 lists a plurality of operational modes for battery 100. Current value column 1004 lists a plurality of current values corresponding to the operational modes listed in operational mode column 1002. For example, in a first row of table 1000, operational mode column 1002 lists first operational mode, and current value column 1004 lists a corresponding first predetermined current value 1006a. Furthermore, in a second row of table 1000, operational mode column 1002 lists second operational mode, and current value column 1004 lists a corresponding second predetermined current value 1006b. Still further, and a third row of table 1000, operational mode column 1002 lists a third operational mode, and current value column 1004 lists a corresponding third predetermined current value 1006c. Table 1000 may include any number of rows that list operational modes and corresponding current values, as desired for a particular application of battery 100.

In an embodiment, discharge phase charge calculator 706 may receive an indication of an operational mode in which battery 100 is operating (e.g., may be received from a processor or other logic of an electrical device powered by battery 100). Discharge phase charge calculator 706 may access table 1000 for a predetermined current value 1006 corresponding to the received operational mode (listed in operational mode column 1002). Discharge phase charge calculator 706 may calculate charge reduction 718 by multiplying the accessed predetermined current value 1006 by the length of time battery 100 operates in the operational mode. In an embodiment, operational modes may be cumulated if battery 100 is capable of operating in multiple operational modes listed in operational mode column 1002 simultaneously. In such a case, multiple predetermined current values 1006 may be accessed in table 1000 corresponding to the multiple operational modes, the multiple predetermined current values 1006 may be summed, and the sum may be multiplied by the length of time battery 100 operates in the multiple operational modes to determine charge reduction 718. For example, table 1000 may include a first operational mode of “connected” in column 1002 that has a predetermined current value of 5 milliamps in column 1004, and a second operational mode of “audio link” in column 1002 that has a predetermined current value of 10 milliamps in column 1004. Battery 100 may operate in an operational mode that is both the “connected” mode and the “audio link” mode. Discharge phase charge calculator 706 may calculate charge reduction 718 by multiplying the sum of the predetermined current values for the “connected” and “audio link” modes (5 milliamps+10 milliamps=15 milliamps) by the amount of time that battery 100 operates in the “connected” and “audio link” modes.

Operational mode current table 1000 may be stored in battery manager 402. Although referred to herein as a “table,” table 1000 may be embodied in various ways, including as other type of data structure such as a text file, a data array, a database, volatile or non-volatile memory data, etc. Current values listed in current value column 1004 may be listed in units of milliamps, Amperes, etc.

Note that although a complete charge cycle is shown in FIG. 8 (first and second charge phase 208 and 210 are both shown completed) prior to any discharge of battery 100 during an operational time period 802, embodiments of the present invention are also applicable to partial charge events and partial discharge events for battery 100 being performed. For example, a discharge event for battery 100 may occur following a partial completion of a charge cycle for battery 100. In an embodiment, an operational time period 802 may begin before a first charge phase 208 is complete, at the transition between first and second charge phases 208 and 210, or during a second charge phase 210 but before the second charge phase 210 is complete. In another example, a charge event for battery 100 may occur following a partial discharging of battery 100. In an embodiment where charging of battery 100 is initiated after being partially discharged, first charge phase 208 may be initiated at a midpoint or other middle portion of first charge phase 208, or first charge phase 208 may be entirely skipped and battery 100 may be charged starting at the beginning or a middle portion of second charge phase 210.

In step 608, a stored charge in the battery is calculated based on a prior determined stored charge in the battery and at least one of the calculated reduction in the charge, the calculated first increase in the charge and the calculated second increase in the charge. For instance, in an embodiment, summer 708 may be configured to perform step 608. As shown in FIG. 7, summer 708 receives a stored charge value 720, first charge increase 714, second charge increase 716, and charge reduction 718. Stored charge value 720 is a previously calculated stored charge for battery 100. In an initial state for battery 100 (e.g., a discharged state), stored charge value 720 may have a zero value. Summer 708 is configured to combine stored charge value 720, and one or more of first charge increase 714, second charge increase 716, and charge reduction 718 to generate stored charge value 720. For example, summer 708 may subtract charge reduction 718 from stored charge value 720, add first charge increase 714 to stored charge value 720, and/or add second charge increase 716 to stored charge value 720 to calculate stored charge value 720, depending on the charge state of battery 100 (e.g., the position in a charge/discharge cycle of battery 100, such as indicated in graphs 810, 820, and 830 in FIG. 8).

Summer 708 may be configured to calculate a running value for the charge stored in battery 100. As charge is added to battery 100 during first charge phase 208 (a constant current charge phase), first charge increase 714 may be added to stored charge value 720 by summer 708. As charge is added to battery 100 during second charge phase 210 (a constant voltage charge phase), second charge increase 716 may be added to stored charge value 720 by summer 708. As charge is removed from battery 100 during an operational time period 802 (corresponding to an operational mode for battery 100), the reduction in charge indicated by charge reduction 718 may be subtracted from stored charge value 720 by summer 708. As shown in FIG. 7, stored charge value 720 may be stored in memory 728. Summer 708 may receive stored charge value 720 from memory 728 as a prior determined stored charge for battery 100.

In step 610, the state of charge of the battery is calculated based on the calculated stored charge. As shown in FIG. 7, SOC calculator 732 receives stored charge value 720. SOC calculator 732 is configured to calculate an estimated state of charge 734 for battery 100 based on stored charge value 720 and SOH 120. For example, SOC calculator 734 may be configured to calculate state of charge 734 according to Equation 3 described above, and shown as follows as Equation 7:

SOC(%)=RC/SOH Equation 7

where
RC=stored charge value 720.
   State of charge 734 may be output from battery manager 402 to be indicated to a user of the electronic device.

In embodiments, battery manager 402, including stored charge estimator 722, first charge phase charge calculator 702, second charge phase charge calculator 704, discharge phase charge calculator 706, summer 708, and SOC calculator 732, may be implemented in hardware, software, firmware, or any combination thereof. For example, any one or more of stored charge estimator 722, first charge phase charge calculator 702, second charge phase charge calculator 704, discharge phase charge calculator 706, summer 708, and SOC calculator 732 may be implemented as computer code configured to be executed in one or more processors. Alternatively, any one or more of stored charge estimator 722, first charge phase charge calculator 702, second charge phase charge calculator 704, discharge phase charge calculator 706, summer 708, and SOC calculator 732 may be implemented as hardware logic/electrical circuitry.

Timer 710 may be any suitable timer implemented in hardware, software, firmware, or any combination thereof. For example, in an embodiment, timer 710 may be analog or digital logic configured as a timer or counter, may be implemented in a processor, and/or may include any other timing mechanism. For example, timer 710 may include an oscillator circuit (e.g., a crystal oscillator). Battery charger 724 may be any suitable type of battery charger, including a commercially available battery charger or proprietary battery charger. Memory 728 may be any type of storage device, including a memory device (e.g., a RAM device, a ROM device, etc.), a hard disc drive, and/or any other suitable type of storage medium.

### Example Embodiments for Adjusting an Estimated State of Charge

In the prior section, embodiments for estimating a state of charge for a battery, such as battery 100, are described. These embodiments may be used to generate a running estimate of the state of charge through any number of charging and discharging cycles for battery 100. In some cases, over time, the accuracy of the estimated state of charge may decrease for various reasons, and thus it may be desired for the estimated state of charge to be adjusted on occasion to improve accuracy. In an embodiment, battery management system 400 shown in FIG. 4 may be configured to adjust the estimated state of charge based on measured parameters of battery 100 to improve its accuracy. For example, FIG. 11 shows a flowchart 1102 that may be performed by battery manager 402. For instance, in an embodiment, process 502 may be included in flowchart 1102 as an initial step.

As shown in FIG. 11, in step 1102, a parameter of the battery is measured. For instance, in embodiments, a current of battery 100, such as a charge current or a discharge current, a voltage of battery 100, or other parameter of battery 100 may be measured. In step 1104, the estimated state of charge is adjusted according to the measured parameter.

In embodiments, state of charge 734 (shown in FIG. 7) may be adjusted based on the measured current, voltage, or other parameter of battery 100. The adjustment enables a more accurate state of charge 734 to be provided by battery manager 402.

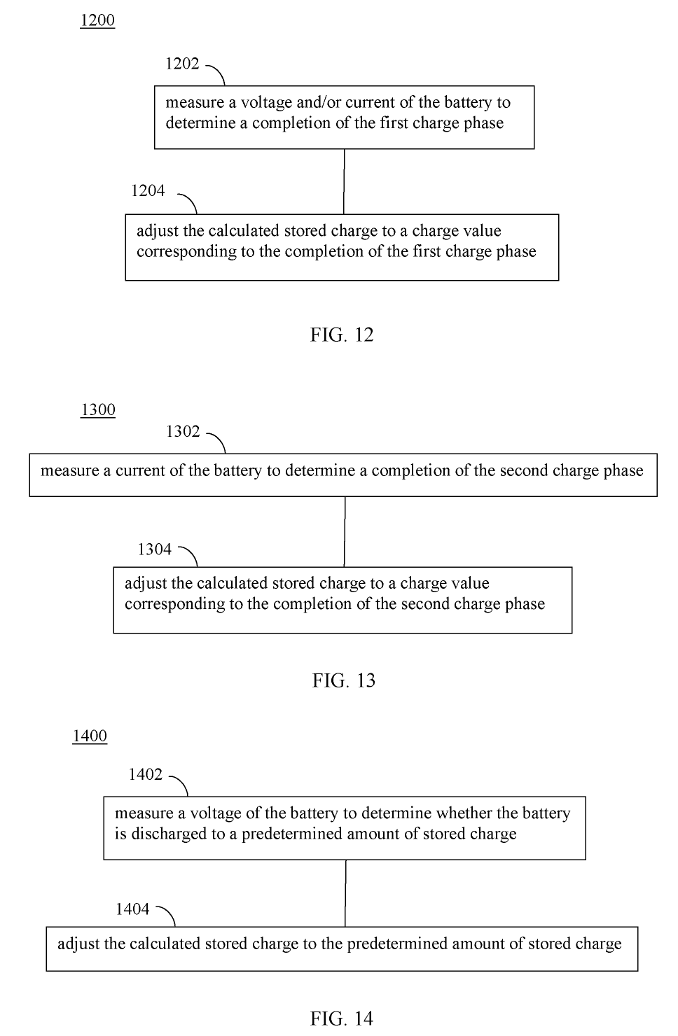

Flowchart 1100 may be performed at any time, and as often as desired. For example, flowchart 1100 may be performed to adjust the state of charge of battery 100 on a periodic basis (e.g., once per hour, once per day, once per charge/discharge cycle, once every 100 charge cycles, etc.) or on a non-periodic basis. Furthermore, flowchart 1100 may be performed by battery manager 402 in various ways, in embodiments. For instance, FIGS. 12-14 each show a respective flowchart providing an example embodiment for flowchart 1100. Battery management system 400 may perform each of the flowcharts shown in FIGS. 12-14, in embodiments. Other structural and operational embodiments will be apparent to persons skilled in the relevant art(s) based on the discussion regarding the flowcharts of FIGS. 12-14.

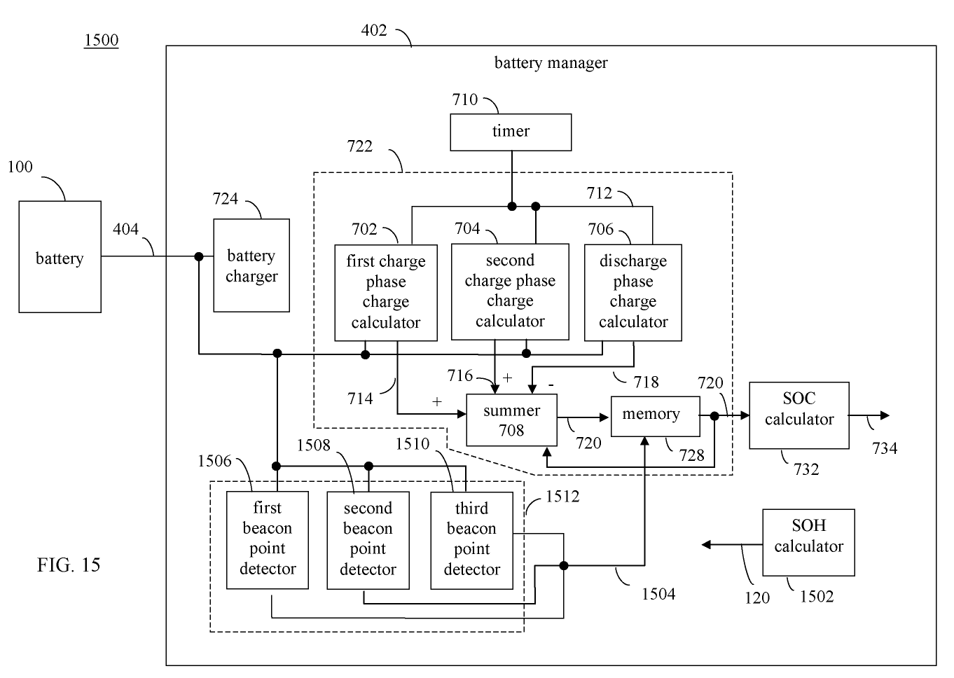

Each of FIGS. 12-14 is described below with respect to FIG. 15. FIG. 15 shows a block diagram of a battery management system 1500, which is an example of battery management system 400 shown in FIG. 4, according to an embodiment of the present invention. As shown in FIG. 15, system 1500 includes battery 100 and battery manager 402. In FIG. 15, battery manager 402 includes timer 710, stored charge estimator 722, battery charger 724, SOC calculator 732, a SOH calculator 1502, and a stored charge adjuster 1512. Stored charge estimator 722 includes first charge phase charge calculator 702, second charge phase charge calculator 704, discharge phase charge calculator 706, summer 708, and memory 728. Stored charge adjuster 1512 is configured to adjust a stored charge estimated by stored charge estimator 722 to reduce or eliminate estimation errors. Stored charge adjuster 1512 includes a first beacon point detector 1506, a second beacon point detector 1508, and a third beacon point detector 1510. As shown in FIG. 15, system 1500 is similar to system 700 shown in FIG. 7. The additional elements of system 1500 are described below with respect to the flowcharts of FIGS. 12-14.

Flowchart 1200 of FIG. 12 is described as follows. In step 1202, a voltage and/or a current of the battery is measured to determine a completion of the first charge phase. For instance, in an embodiment, first beacon point detector 1506 may be configured to perform step 1202. First beacon point detector 1506 may be configured to monitor a first “beacon point,” which is a point in time that corresponds to a transition from first charge phase 208 to second charge phase 210 during a charge cycle for battery 100. For example, FIG. 8 shows a first beacon point 816 positioned on the time scale of graphs 810, 820, and 830 at the transition from first charge phase 208 to second charge phase 210. First beacon point detector 1506 is configured to detect first beacon point 816.

When first beacon point 816 is detected by first beacon point detector 1506, first charge phase 208 is considered to be completed.

In an embodiment, first beacon point detector 1506 may detect first beacon point 816 by measuring a voltage and/or a current of battery 100 (e.g., on electrical connection 404) that indicates the transition from first charge phase 208 to second charge phase 210. With regard to measuring a voltage, at first beacon point 816, battery 100 may have a pre-determined known voltage (e.g., which may be indicated in a datasheet) corresponding to the transition from first charge phase 208 to second charge phase 210. First beacon point detector 1506 may be configured to monitor the voltage of battery 100 until this predetermined known voltage corresponding to the transition from first charge phase 208 to second charge phase 210 is measured, to detect first beacon point 816. With regard to measuring a current, a charge current supplied to battery 100 may transition from a constant current to a decreasing current at first beacon point 816. First beacon point detector 1506 may be configured to monitor the current supplied to battery 100 until this transition from constant charge current to a decreasing charge current is measured, to detect first beacon point 816.

In an example, first beacon point detector 1506 may be configured to measure a pre-determined known voltage to detect first beacon point 816. The predetermined known voltage corresponding to first beacon point 816 may be 4.1 V for example. When first beacon point detector 1506 measures 4.1 V on electrical connection 404 during first charge phase 208, first beacon point 816 is detected.

In another example, first beacon point detector 1506 may be configured to measure the transition from constant current to a decreasing current to detect first beacon point 816. When first beacon point detector 1506 measures a decrease in current from the constant current, first beacon point 816 is detected. For example, first beacon point detector 1506 may be configured to indicate that first beacon point 816 is detected if the measured current decreases by a predetermined percentage or amount from a substantially constant level, such as a decrease of 5% or other percentage or current amount.

Referring back to flowchart 1200, in step 1204, the calculated stored charge is adjusted to a charge value corresponding to the completion of the first charge phase. For instance, in an embodiment, first beacon point detector 1506 may be configured to perform step 1204. First beacon point detector 1506 may be configured to calculate a charge value corresponding to the completion of first charge phase 208, which may be used to replace stored charge value 720. The calculated charge value may be used to replace stored charge value 720 because of an accumulated error that may be present in stored charge value 720 due to the charge estimations techniques described above, for example. At first beacon point 816 (the transition between first charge phase 208 and second charge phase 210), the charge value stored in battery 100 may be a predetermined percentage of the state of health of battery 100. This predetermined percentage may be determined from a data sheet for battery 100, for instance. The replacement charge value may be calculated by multiplying a current state of health of battery 100 by the predetermined known percentage value.

For example, when first beacon point 816 is detected, the estimated stored charge may be 300 C. However, a current state of health for battery 100 may be 360 C (100 mAH), and for the battery type of battery 100, the state of charge may be known to be 70% of the current state of health. Thus, when first beacon point 816 is detected, first beacon point detector 1506 may calculate the stored charge for battery 100 according to Equation 8:

stored charge=predetermined percentage×SOH, Equation 8

which in the current example may be calculated as:

$$stored charge = 70 \% \times 360 C \\ = 252 C$$

In the current example, as shown in FIG. 15, beacon point detector 1506 may generate an adjusted stored charge 1504 to be 252 C. This calculated stored charge value of 252 C is used to replace the estimated stored charge value of 300 C. Adjusted stored charge 1504 is received by memory 728, and replaces the stored charge value stored in memory 728.

In one situation, the estimated stored charge may be greater than the calculated adjusted stored charge (e.g., the estimated stored charge may be 300 C, while the calculated adjusted stored charge may be 252 C). In such case, first beacon point detector 1506 may be configured to hold stored charge 720 at the adjusted stored charge value (e.g., 252 C) (e.g., by providing the calculated adjusted stored charge value to memory 728 as adjusted stored charge 1504 when the estimated stored charge reaches the value of the calculated stored charge) until first beacon point 816 is detected. In another situation, the estimated stored charge may be less than the calculated replacement storage charge (e.g., the estimated stored charge may be 200 C, while the calculated adjusted stored charge may be 252 C). In such case, first beacon point detector 1506 may be configured to provide the calculated adjusted stored charge value to memory 728 as adjusted stored charge 1504 when first beacon point 816 is detected (e.g., upon detecting first beacon point 816, stored charge 720 is increased from 200 C directly to 252 C).

Flowchart 1300 of FIG. 13 is described as follows. In step 1302, a current of the battery is measured to determine a completion of the second charge phase. For instance, in an embodiment, second beacon point detector 1508 may be configured to perform step 1302. Second beacon point detector 1508 may be configured to monitor a second “beacon point,” which is a point in time that corresponds to a completion of second charge phase 210 for battery 100, where battery 100 is substantially fully charged. For example, FIG. 8 shows a second beacon point 818 positioned on the time scale of graphs 810, 820, and 830 at the completion of second charge phase 210. Second beacon point detector 1508 is configured to detect second beacon point 818. When second beacon point 818 is detected by second beacon point detector 1508, second charge phase 210 is considered to be completed.

In an embodiment, second beacon point detector 1508 may detect second beacon point 818 by measuring a current of battery 100 (e.g., on electrical connection 404) that indicates second charge phase 210 is complete. At the completion of second charge phase 210, a charge current supplied to battery 100 may be near or equal to zero. Second beacon point detector 1508 may be configured to monitor the current supplied to battery 100 until a zero or near zero current is measured, to detect second beacon point 818. For example, second beacon point detector 1508 may be configured to indicate that second beacon point 818 is detected if the measured current goes below a predetermined threshold current value, which may be predetermined based on the particular battery type for battery 100, such as 5 milliamps or other threshold current value. In an alternative embodiment, second beacon point detector 1508 may detect second beacon point 818 by determining the passage of a predetermined amount of time (e.g., by monitoring clock signal 712) corresponding to an average amount of time expected to complete second charge phase 210.

In step 1304, the calculated stored charge is adjusted to a charge value corresponding to the completion of the second charge phase. For instance, in an embodiment, second beacon point detector 1508 may be configured to perform step 1304. Second beacon point detector 1508 may be configured to calculate a charge value corresponding to the completion of second charge phase 210, which may be used to replace stored charge value 720. The calculated charge value may be used to replace stored charge value 720 because of an accumulated error that may be present in stored charge value 720 due to the charge estimations techniques described above, for example. For example, at second beacon point 818 (the completion of second charge phase 210), the charge value stored in battery 100 should be equal to the state of health of battery 100.

For instance, when second beacon point 818 is detected, the estimated stored charge may be 300 C. However, a current state of health for battery 100 may be 360 C (100 mAH). Thus, when second beacon point 818 is detected, second beacon point detector 1508 may generate an adjusted stored charge 1504 of 360 C, which is the current state of health for battery 100. This adjusted stored charge value of 360 C is used to replace the estimated stored charge value of 300 C. Adjusted stored charge 1504 is received by memory 728, and replaces the stored charge value stored in memory 728.

In one situation, the estimated stored charge may be greater than the current state of health for battery 100 (e.g., the estimated stored charge may be 400 C, while the current state of health may be 360 C). In such case, second beacon point detector 1508 may be configured to hold stored charge 720 at the replacement stored charge value (e.g., 360 C) (e.g., by providing the calculated replacement stored charge value to memory 728 as adjusted stored charge 1504 when the estimated stored charge reaches the value of the calculated replacement stored charge) until second beacon point 818 is detected. In another situation, the estimated stored charge may be less than the current state of health of battery 100 (e.g., the estimated stored charge may be 200 C, while the current state of health may be 360 C). In such case, second beacon point detector 1508 may be configured to provide the replacement stored charge value to memory 728 as adjusted stored charge 1504 when second beacon point 818 is detected (e.g., upon detecting second beacon point 818, stored charge 720 is increased from 200 C directly to 360 C).

Flowchart 1400 of FIG. 14 is described as follows. In step 1402, a voltage of the battery is measured to determine whether the battery is discharged to a predetermined amount of stored charge. For instance, in an embodiment, third beacon point detector 1510 may be configured to perform step 1402. Third beacon point detector 1510 may be configured to monitor a third “beacon point,” which is a point in time that corresponds to battery 100 being discharged to a predetermined charge level. For example, FIG. 8 shows a third beacon point 822 positioned on the time scale of graphs 810, 820, and 830 near the completion of third operational time period 802c. Third beacon point detector 1510 is configured to detect third beacon point 822. When third beacon point 822 is detected by third beacon point detector 1510, battery 100 has discharged to a predetermined amount of stored charge.

In an embodiment, third beacon point detector 1510 may detect third beacon point 822 by measuring a voltage of battery 100 (e.g., on electrical connection 404) that indicates that battery 100 has discharged to the predetermined amount of stored charge. Third beacon point detector 1510 may be configured to monitor the voltage of battery 100 until a predetermined voltage is reached, to detect third beacon point 822. For example, third beacon point detector 1510 may be configured to indicate that third beacon point 822 is detected if the measured voltage decreases to a predetermined threshold voltage value, which may be any desired voltage value. The predetermined threshold voltage value may correspond to any desired predetermined amount of stored charge, which may be indicated by a percentage of full charge, for example. For instance, in the example of FIG. 8, third beacon point 822 is selected to have a voltage value of 3.45 V, indicating that battery 100 is discharged to 2% of full charge. If the current state of health (i.e., a full charge) of battery 100 is 360 C, third beacon point detector 1510 can determine that battery 100 should be discharged to 7.2 C (e.g., 2% of 360 C=7.2 C) when third beacon point 1510 is detected by the measurement of 3.45 V.

In step 1404, the calculated stored charge is adjusted to the predetermined amount of stored charge. For instance, in an embodiment, third beacon point detector 1510 may be configured to perform step 1404. Third beacon point detector 1510 may be configured to provide a charge value corresponding to the predetermined amount of stored charge, which may be used to replace stored charge value 720. The provided charge value may be used to replace stored charge value 720 because of an accumulated error that may be present in stored charge value 720 due to the charge estimations techniques described above, for example. At third beacon point 822, the charge value stored in battery 100 may be calculated as described above, by multiplying the predetermined percentage of full charge indicated by third beacon point 822 by the current state of health of battery 100.

For example, when third beacon point 822 is detected, the estimated stored charge may be 25 C. However, a current state of health for battery 100 may be 360 C (100 mAH). In the current example, where the predetermined amount of stored charge at third beacon point 822 should be 2% of a full charge, when third beacon point 822 is detected, third beacon point detector 1510 may generate a adjusted stored charge 1504 of 2%×360 C=7.2 C. This adjusted stored charge value of 7.2 C is used to replace the estimated stored charge value of 25 C. Adjusted stored charge 1504 is received by memory 728, and replaces the stored charge value stored in memory 728.

In one situation, the estimated stored charge may be greater than the predetermined amount of stored charge for battery 100 (e.g., the estimated stored charge may be 25 C, while the predetermined amount of stored charge may be 2% or 7.2 C). In such case, third beacon point detector 1510 may be configured to hold stored charge 720 at the adjusted stored charge value (e.g., 7.2 C) (e.g., by providing the calculated adjusted stored charge value to memory 728 as adjusted stored charge 1504 when the estimated stored charge reaches the predetermined amount of stored charge) until third beacon point 822 is detected. In another situation, the estimated stored charge may be less than the predetermined amount of stored charge of battery 100 (e.g., the estimated stored charge may be 5 C, while the predetermined amount of stored charge may be 2% or 7.2 C). In such case, third beacon point detector 1510 may be configured to provide the adjusted to stored charge value to memory 728 as adjusted stored charge 1504 when third beacon point 822 is detected (e.g., upon detecting third beacon point 822, stored charge 720 is increased from 5 C directly to 7.2 C).

Note that in embodiments, third beacon point detector 1510 may be configured to monitor one or more further beacon points in addition to third beacon point 822, which each indicate battery 100 is discharged to a corresponding predetermined amount of stored charge. For instance, a fourth beacon point 824 is shown having a voltage value of 3.1 V, indicating that battery 100 is 0.5% charged. Third beacon point detector 1510 may be configured to monitor fourth beacon point 824 in addition to, or alternatively to third beacon point 822, and to adjust the stored charge for battery 100 accordingly, in an embodiment.

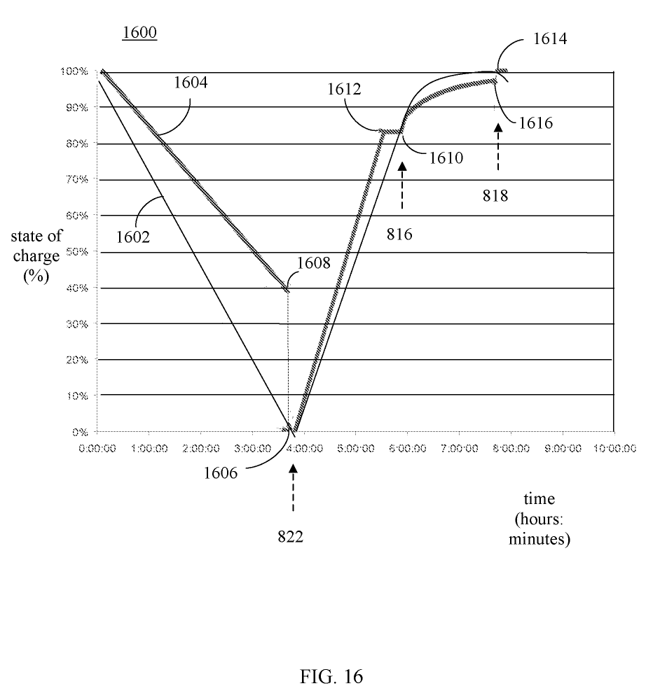

FIG. 16 shows a graph 1600 of the state of charge (SOC) for battery 100 during an example discharge and charge cycle, according to an embodiment of the present invention. FIG. 16 is provided to illustrate examples of adjustments to an estimated SOC that are enabled by first-third beacon point detectors 1506-1510 and flowcharts 1200-1400. In FIG. 16, graph 1600 includes a first plot 1602 of an actual state of charge for battery 100 and a second plot 1604 of an estimated SOC for battery 100. State of charge is plotted on the y-axis versus time on the x-axis in graph 1600.

A first point 1606 on first plot 1602 and a second point 1608 on second plot 1604 illustrate an adjustment of the state of charge based on third beacon point 822, according to flowchart 1400. As shown in FIG. 16, an estimated state of charge at third beacon point 822 indicated by second point 1608 is approximately 40%. Third beacon point detector 1510 may perform flowchart 1400 to adjust the estimated state of charge to the actual state of charge indicated by point 1606, which may be 0% in the example of FIG. 16.

A third point 1610 on first plot 1602 and a fourth point 1612 on second plot 1604 illustrate an adjustment of the state of charge based on first beacon point 816, according to flowchart 1200. As shown in FIG. 16, an estimated state of charge indicated by fourth point 1612 is approximately 83%, and has an increasing trend prior to reaching first beacon point 816. First beacon point detector 1506 may perform flowchart 1200 to adjust the estimated state of charge to the actual state of charge indicated by third point 1610, which is 83%. Thus, in the example of FIG. 16, first beacon point detector 1506 may hold the estimated state of charge at 83% from fourth point 1612 until first beacon point 816 is detected at third point 1610.

A fifth point 1614 on first plot 1602 and a sixth point 1616 on second plot 1604 illustrate an adjustment of the state of charge based on second beacon point 818, according to flowchart 1300. As shown in FIG. 16, an estimated state of charge at second beacon point 818 indicated by sixth point 1616 is approximately 96%. Second beacon point detector 1508 may perform flowchart 1300 to adjust the estimated state of charge to the actual state of charge indicated by fifth point 1614, which is 100% in the example of FIG. 16.

In embodiments, stored charge adjuster 1512, SOH calculator 1502, first beacon point detector 1506, second beacon point detector 1508, and third beacon point detector 1510 may be implemented in hardware, software, firmware, or any combination thereof. For example, any one or more of stored charge adjuster 1512, SOH calculator 1502, first beacon point detector 1506, second beacon point detector 1508, and third beacon point detector 1510 may be implemented as computer code configured to be executed in one or more processors. Alternatively, any one or more of stored charge adjuster 1512, SOH calculator 1502, first beacon point detector 1506, second beacon point detector 1508, and third beacon point detector 1510 may be implemented as hardware logic/electrical circuitry. In embodiments, any one or more of first-third beacon point detectors 1506-1510 may be present.

As shown in FIG. 15, SOH calculator 1502 may be configured to calculate SOH 120 for battery 100. SOH 120 calculated by SOH calculator 1502 may be received by any of first, second, and third beacon point detectors 1506, 1508, and 1510, and/or any other elements of battery manager 402 that use SOH 120 in any manner. SOH 120 generated by SOH calculator 1502 may be a most recent state of health determined for battery 100, or may be an average of a predetermined number of state of health values previously determined by SOH calculator 1502. SOH calculator 1502 may be configured to calculate SOH 120 for battery 100 in any manner described herein or otherwise known. For example, in an embodiment, SOH 120 may be calculated as described in co-pending U.S. patent application Ser. No. 12/018,425, titled “Method and System for Tracking Battery State-of-Health,” which is incorporated by reference herein in its entirety.

### Example Electrical Device Embodiments

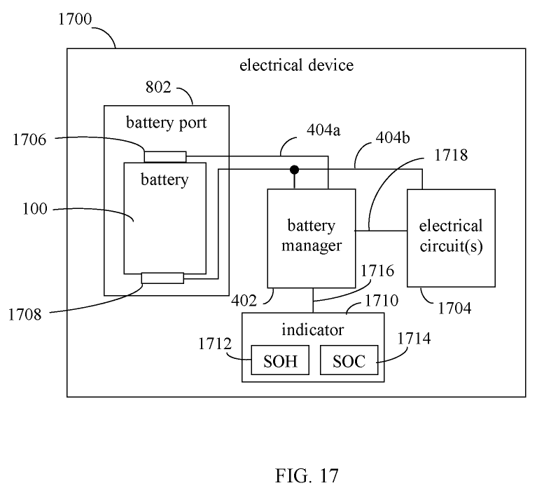

Battery managers 402 shown in FIGS. 4, 7, and 11, any combination thereof, and/or any other embodiment described herein, may be implemented in any type of electronic/electrical device that includes one or more rechargeable batteries. For example, FIG. 17 shows a block diagram of an example electrical device 1700 that incorporates battery manager 402, according to an embodiment of the present invention. As shown in FIG. 17, electrical device 1700 includes a battery port 1702, electrical circuit(s) 1704, and battery manager 402. Battery port 1702 is any type of battery port, including a recessed area, slot, or other opening configured to receive battery 100. In the example of FIG. 17, battery port 1702 includes a first contact 1706 and a second contact 1708. A first terminal of battery 100 (e.g., terminal 102 or terminal 104 shown in FIG. 1) makes contact with first contact 1706, and a second terminal of battery 100 makes contact with second contact 1708. First and second contacts 1706 and 1708 are respectively electrically coupled by first and second electrical connections 404a and 404b to battery manager 402 to provide a path for electrical current to battery manager 402 (and to electrical circuit(s) 1704 through battery manager 402).

In an embodiment, battery manager 402 may process a voltage received across first and second electrical connections 404a and 404b from battery 100 to generate a voltage signal that is output on a third electrical connection 1718. For instance, battery manager 402 may filter the received voltage, may set the output voltage signal to a predetermined voltage value (e.g., using a voltage regulator), and/or may otherwise process the received voltage. Second electrical connection 404b (e.g., a ground signal) and third electrical connection 1718 (e.g., a power signal) are received by electrical circuit(s) 1704, to provide power to electrical circuit(s) 1704 from battery 100.

Electrical connections 404a, 404b, and 1718 may each include one or more electrically conductive connections, such as wires, cables, connectors, metal strips, etc, as would be known to persons skilled in the relevant art(s). First and second contacts 1706 and 1708 may be any type of contacts, conventional or otherwise, including metal contacts, as would be known to persons skilled in the relevant art(s). Note that the particular configuration for electrical device 1700 shown in FIG. 17 is provided for purposes of illustration, and that electrical device 1700 may be configured in alternative ways, as would be known to persons skilled in the relevant art(s).

Electrical device 1700 may be any sort of electrical device that uses electrical power, and that includes one or more batteries. For example, electrical device 1700 may be a stationary device or a portable device. Example devices for electrical device 1700 include mobile computers (e.g., a Palm® device, a personal digital assistant (PDA), a laptop computer, a notebook computer, etc.), mobile email devices (e.g., a RIM Blackberry® device), mobile phones (e.g., a cell phone), a handheld media player such as a handheld music and/or video player (e.g., a Microsoft Zune™ device, an Apple iPod™ device, etc.), a handheld game console (e.g., a Nintendo DS™, a PlayStation Portable™, etc.), a wireless headset (e.g., a Bluetooth® headset), a personal navigation device (e.g. a handheld global position system (GPS) device), a handheld digital video camera, and any other electrical device. Electrical circuit(s) 1704 may include any number of one or more electrical circuits providing functionality for electrical device 1700, including computing/processing circuits, logic circuits, electromechanical circuits, video circuits, audio circuits, communications circuits, image capturing circuits, etc.

Electrical device 1700 may optionally include an indicator 1710, as shown in FIG. 17. Indicator 1710 is configured as a battery state of health indicator to provide an indication of the calculated state of health of battery 100 and/or a calculated state of charge of battery 100. Indicator 1710 receives a battery health information signal 1716 from battery manager 402, which may include the calculated state of health and/or state of charge. As shown in FIG. 17, indicator 1710 may display or otherwise output a state of health 1712 and/or a state of charge 1714 calculated by SOH calculator 1502 and SOC calculator 732, respectively. Indicator 1710 may be implemented in any manner to provide an indication of the calculated state of health 1712 and/or calculated state of charge 1714 of battery 100. For example, indicator 1710 may include one or more light emitting diodes (LED), may include a textual readout and/or a graphical icon displayed by a display of electrical device 1700, and/or may include any other visual and/or audio output device of electrical device 1700. In an embodiment where indicator 1710 includes one or more LEDs, a color, an intensity, a number of illuminated LEDs, and/or any other configuration of the LEDs may be used to indicate a calculated state of health 1712 and/or state of charge 1714. In an embodiment where indicator 1710 includes a textual readout, the textual readout can display state of health 1712 and/or state of charge 1712 as actual values, as percentages representative of the state of health and/or state of charge, and/or according to any other textual indication. In an embodiment where indicator includes a graphical icon, the graphical icon may indicate state of health 1712 and/or state of charge 1714 in any manner, such as by showing a partial battery icon, etc.

In another embodiment, indicator 1710 may be located in a second device that is separate from electrical device 1700. Electrical device 1700 may include a transmitter or other interface for transmitting the state of health and/or the state of charge output by battery manager 402 in battery health information signal 1716 to the second device. For instance, in an embodiment, electrical device 1700 may be a headset powered by battery 100, and the second device may be a telephone (e.g., a portable phone, such as a cell phone). The headset may transmit the state of health and/or state of charge information for battery 100 to the telephone. Indicator 1710 may be a display of the telephone, which may display state of health 1712 and/or state of charge 1714 received from electrical device 1700.

In an embodiment, battery charger 724 (FIG. 7) may be included in electrical device 1700 (e.g., in battery manager 402 or external to battery manager 402), or may be external to electrical device 1700.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method for estimating a state of charge for a rechargeable battery of an electronic device, comprising:
calculating a first increase in a charge stored in the battery during a first charge phase of the battery in which a substantially constant charge current is received by the battery for a first amount of time;
calculating a second increase in the charge stored in the battery during a second charge phase of the battery in which a decreasing charge current is received by the battery for a second amount of time;
calculating a reduction of the charge stored in the battery by multiplying a predetermined discharge current corresponding to an operational mode of the electronic device by an amount of time that the electronic device is in the operational mode;
calculating a stored charge in the battery based on a prior determined stored charge in the battery and at least one of the calculated reduction in the charge, the calculated first increase in the charge, or the calculated second increase in the charge; and
calculating a state of charge of the battery based on the calculated stored charge.

2. The method of claim 1, further comprising:
measuring a parameter of the battery; and
adjusting the calculated state of charge of the battery according to the measured parameter.

3. The method of claim 2, wherein said measuring comprises:
measuring a voltage and/or current of the battery to determine a completion of the first charge phase; and
wherein said adjusting comprises:
adjusting the calculated stored charge to a charge value corresponding to the completion of the first charge phase, and
calculating the state of charge of the battery based on the adjusted stored charge.

4. The method of claim 2, wherein said measuring comprises:
measuring a current of the battery to determine a completion of the second charge phase; and
wherein said adjusting comprises:
adjusting the calculated stored charge to a charge value corresponding to the completion of the second charge phase, and
calculating the state of charge of the battery based on the adjusted stored charge.

5. The method of claim 2, wherein said measuring comprises:
measuring a voltage of the battery to determine whether the battery is discharged to a predetermined amount of stored charge; and
wherein said adjusting comprises:
adjusting the calculated stored charge to the predetermined amount of stored charge, and
calculating the state of charge of the battery based on the adjusted stored charge.

6. The method of claim 1, wherein said calculating the state of charge of the battery based on the calculated stored charge comprises:
calculating the state of charge (SOC) of the battery as a percentage according to
SOC of the battery=100×CSC/SOH,
where
SOH=a state of charge of the battery, and
CSC=the calculated stored charge.

7. The method of claim 1, further comprising:
displaying the calculated state of charge of the battery.

8. A battery manager, comprising:
a first charge phase charge calculator configured to calculate a first increase in a charge stored in the battery during a first charge phase of the battery in which a substantially constant charge current is received by the battery for a first amount of time;
a second charge phase charge calculator configured to calculate a second increase in the charge stored in the battery during a second charge phase of the battery in which a decreasing charge current is received by the battery for a second amount of time;
a third charge phase charge calculator configured to calculate a reduction of the charge stored in the battery by multiplying a predetermined discharge current corresponding to an operational mode of the electronic device by an amount of time that the electronic device is in the operational mode;
a summer configured to calculate a stored charge in the battery based on a prior determined stored charge in the battery and at least one of the calculated reduction in the charge, the calculated first increase in the charge, or the calculated second increase in the charge; and
a state of charge calculator configured to calculate the state of charge of the battery based on the calculated stored charge.

9. The battery manager of claim 8, further comprising:
a stored charge adjuster configured to measure a parameter of the battery, and to calculate an adjusted stored charge for the battery according to the measured parameter.

10. The battery manager of claim 9, wherein the stored charge adjuster comprises:
a beacon point detector configured to measure a voltage and/or current of the battery to determine a completion of the first charge phase, and to adjust the calculated stored charge to a charge value corresponding to the completion of the first charge phase.

11. The battery manager of claim 9, wherein the stored charge adjuster comprises:
a beacon point detector configured to measure a current of the battery to determine a completion of the second charge phase, and to adjust the calculated stored charge to a charge value corresponding to the completion of the second charge phase.

12. The battery manager of claim 9, wherein the stored charge adjuster comprises:
a beacon point detector configured to measure a voltage of the battery to determine whether the battery is discharged to a predetermined amount of stored charge, and to adjust the calculated stored charge to the predetermined amount of stored charge.

13. The system of claim 8, wherein the battery is a lithium battery.

14. The system of claim 8, further comprising:
an indicator configured to display the calculated state of charge.

15. A method for tracking a state of charge of a rechargeable battery of an electronic device, comprising:
estimating the state of charge of the battery;
measuring a parameter of the battery; and
adjusting the estimated state of charge of the battery according to the measured parameter.

16. The method of claim 15, wherein said measuring comprises:
measuring a voltage and/or current of the battery to determine a completion of a constant current charge phase for the battery; and
wherein said adjusting comprises:
adjusting a stored charge determined for the battery to a charge value corresponding to the completion of the constant current charge phase, and
calculating the state of charge of the battery based on the adjusted stored charge.

17. The method of claim 15, wherein said measuring comprises:
measuring a current of the battery to determine a completion of a constant voltage charge phase for the battery; and
wherein said adjusting comprises:
adjusting a stored charge determined for the battery to a charge value corresponding to the completion of the constant voltage charge phase, and
calculating the state of charge of the battery based on the adjusted stored charge.

18. The method of claim 15, wherein said measuring comprises:
measuring a voltage of the battery to determine whether the battery is discharged to a predetermined amount of stored charge; and
wherein said adjusting comprises:
adjusting a stored charge determined for the battery to the predetermined amount of stored charge, and
calculating the state of charge of the battery based on the adjusted stored charge.

19. The method of claim 15, further comprising:
displaying the calculated state of charge of the battery.

20. A battery-powered electrical device, comprising:
a battery manager that includes a battery charger, a timer, and a stored charge estimator configured to estimate a state of charge of a battery; and
a battery port configured to interface the battery with the device;
wherein the stored charge estimator includes
a first charge phase charge calculator configured to calculate a first increase in a charge stored in the battery during a first charge phase of the battery in which a substantially constant charge current is received by the battery for a first amount of time;
a second charge phase charge back later configured to calculate a second increase in the charge stored in the battery during a second charge phase of the battery in which a decreasing charge current is received by the battery for a second amount of time;
a third charge phase charge calculator configured to calculate a reduction of the charge stored in the battery by multiplying a predetermined discharge current corresponding to an operational mode of the electronic device by an amount of time that the electronic device is in the operational mode;
a summer configured to calculate a stored charge in the battery based on a prior determined stored charge in the battery and at least one of the calculated reduction in the charge, the calculated first increase in the charge, or the calculated second increase in the charge; and
a state of charge calculator configured to calculate the state of charge of the battery based on the calculated stored charge.

21. The battery-powered electrical device of claim 20, wherein the battery manager further includes:
a stored charge adjuster configured to measure a parameter of the battery, and to calculate an adjusted stored charge for the battery according to the measured parameter.
